(19) United States
(12) Patent Application Publication
(10) Pub. No.: US 2024/0405741 A1
(43) Pub. Date: Dec. 5, 2024

(54) Distributed Attenuators With Uniform Electric Field

(71) Applicant: Anton Manolescu, San Jose, CA (US)

(72) Inventor: Anton Manolescu, San Jose, CA (US)

(21) Appl. No.: 18/205,519

(22) Filed: Jun. 3, 2023

(51) Int. Cl. H03H 7/24; H03H 11/24

(52) U.S. Cl. CPC H03H 7/24; H03H 11/24

(57) ABSTRACT

An attenuator is described, obtained from a single resistive film deposited on an insulated substrate provided with three or more conductive terminals serving as input, output and common electrodes for electrical signals. These terminals are formed over the edges of the resistive film in a proper manner so as their position, lengths and the shape of the resistive film determine an uniform electric field and uniform current density lines throughout the resistive film with a precise ratio between the input current and the output current, and specific input and output resistances. The reliability of the attenuator is significantly improved.

### BACKGROUND

Distributed resistive film devices obtained using thick film or thin film technology are used as electrical signal attenuators where a precise lowering of an input signal level is necessary, matching the input and output resistances of the source and of the load, respectively. They represent a promising replacement for similar devices built with discrete components regarding size, precision, bandwidth and cost.

It is well known that, using many technologies available today, it is possible to replace interconnected lumped resistors connected in a by a single resistive film, the single resistive film having conductive terminals situated on its boundary, so as to obtain an identical circuit response. Starting with the 1950s, the so called distributed resistive structures were studied as a convenient replacement of networking discrete resistors that were previously using only lumped resistors.

A conventional (lumped) resistive signal attenuator is obtained with three or four resistors connected as T, Pi, square, bridge or other similar circuits using lumped components. Using precise computed values of these components and respecting tight tolerances for the values of these components a wide range of signal attenuation factors can be obtained, simultaneously keeping the signal source and load impedance matched with the input and output of the resistive network in order to maintain their useful behavior until the highest possible frequency of interest.

Previously known examples of resistive signal attenuators use a single sheet of resistive film in order to replace the individual resistors therefore they are named distributed attenuators. They try to mimic the connections of equivalent lumped ones providing the rectangular resistive film used with conducting contacts placed on their boundary, with lengths and positions carefully chosen as to obtain the same electrical behavior as their equivalent lumped networks.

Some examples of resistive signal attenuators using a single sheet of resistive film are shown in FIGS. 1A-C. These attenuators include a resistive film 10, an input terminal 20, an output terminal 30, and a common terminal 40. In FIG. 1B the common terminal consists of two sections that are configured on opposite sides of the resistive sheet 10.

Attempts to replace a resistive (lossy) signal attenuator (a simple device) by a device formed over a single polygonal shaped resistive film provided with three or four conductive terminal sections on its boundary were not fully successful due to reliability issues, such as breakdown by overheating. It is thus important to improve the reliability of attenuators that use a resistive film.

### SUMMARY

A resistive attenuator using a single resistive film is disclosed. The attenuator has terminals formed over the entirety of parallel edges. The electric field lines and the current density lines are all parallel to one another, exhibiting an uniform field pattern. The attenuator exhibits an improved reliability.

### BRIEF DESCRIPTION OF THE DRAWINGS

For a better understanding of the invention an embodiment thereof is now described purely by way of non-limiting examples and in reference to the attached drawings, in which:

FIGS. 1A, 1B, and 1C are drawings which represent three structures of resistive attenuators known in the art.

FIG. 2A presents a resistive distributed attenuator with uniform electric field in accordance with a first embodiment of the present invention.

FIG. 2B presents the electric field pattern in the embodiment shown in FIG. 2A.

FIG. 3A presents a balanced resistive distributed attenuator with uniform electric field in accordance with a second embodiment of the present invention.

FIG. 3B presents the electric field pattern in the embodiment shown in FIG. 3A.

FIG. 4A presents a resistive distributed attenuator with uniform electric field in accordance with a third embodiment of the present invention. FIG. 4B presents the electric field pattern in the embodiment shown in FIG. 4A.

FIG. 5 presents a resistive distributed attenuator with uniform electric field formed over a cylindrical rod or tube or on a flexible plastic sheet in accordance with a fourth embodiment of the present invention.

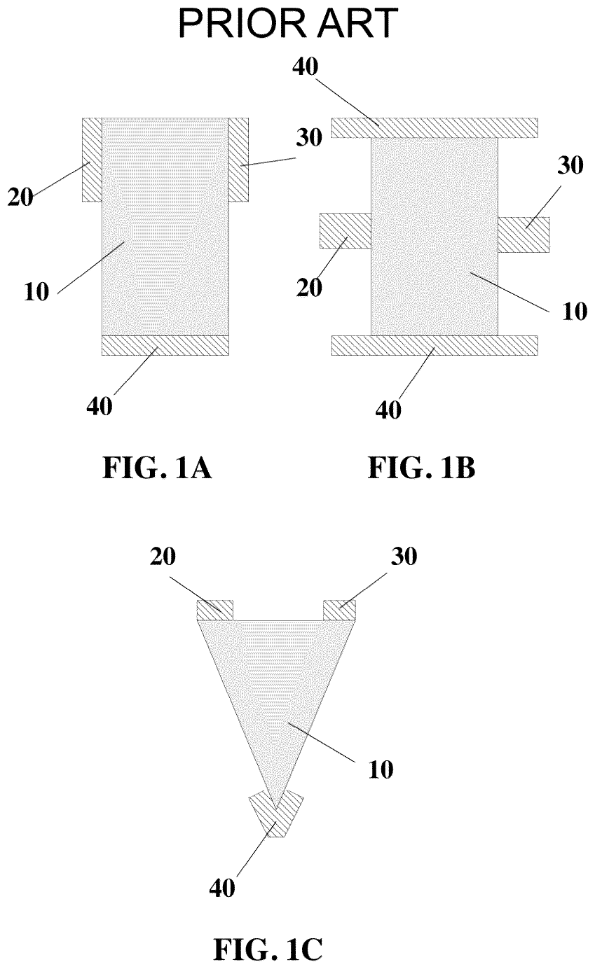

### DETAILED DESCRIPTION OF THE INVENTION

The invention describes a class of distributed resistive film devices used as electrical signal attenuators which are characterized by an uniform electrical field inside a single resistive film. The resistive film is uniform, meaning that its thickness and resistivity are the same throughout the film. An uniform bidimensional field in an uniform resistive film is defined as a field that has all the field lines equidistant and parallel to one another throughout the resistive film. The field may be an electric field, or a current density lines field. A person skilled in the art recognizes that in such an uniform electric field, equipotential lines are equally spaced and crossing at right angles the electric field lines, and the current density lines are also uniform (i.e., are parallel with one another and equidistant). An attenuator with uniform current density lines ensures that the current flow is uniformly distributed over the entire resistive film, thus eliminating regions that concentrate current (“current crowding”). Accordingly, such an attenuator exhibits improved reliability. Consider an attenuator coupled to a signal source at the attenuator input, and working on a load coupled to an attenuator output. The attenuation of an attenuator is defined as the “voltage” attenuation, meaning the ratio between the voltage at the load and the voltage at the input of the attenuator.

When referring to a polygon that has a plurality of edges, it is understood that the plurality of edges consists of the totality of edges of the polygon. Considering a rectangle of a resistive sheet, the rectangle having two opposite edges entirely covered by a terminal, the resistance between the two terminals is well known in the art to be the sheet resistivity (in Ohms/square) multiplied by the aspect ratio of the rectangle (defined as the ratio between the length between the terminals and the length of an edge covered by a terminal, i.e., the number of squares).

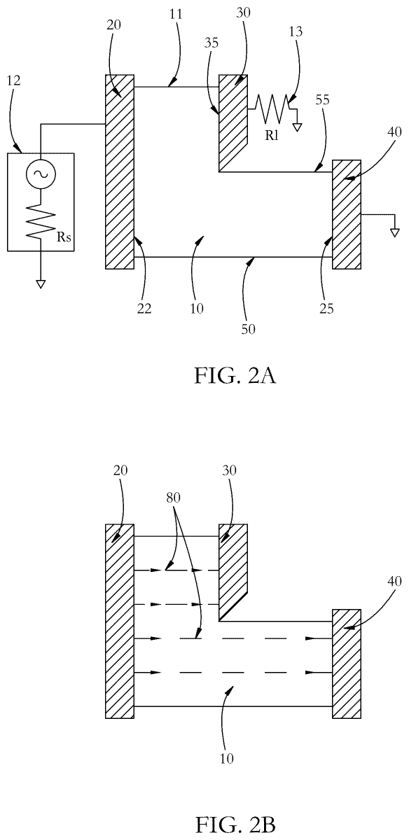

In FIG. 2A a three terminal resistive distributed attenuator with uniform electric field and uniform current density lines inside a single resistive film 10 is shown, according to the first embodiment of the present invention. The polygonal shaped resistive film 10 has a plurality of edges, each edge being parallel to a vertical axis (e.g., edge 22) or parallel to a horizontal axis (e.g., edge 50). Over the entirety of the largest edge 22 of the polygonal resistive film 10 a conducting input terminal 20 is formed. Input terminal 20 is coupled to an input signal source 12, having a signal source resistance Rs. A portion of the input current flows from terminal 20 towards the common terminal 40, which is formed over the entirety of edge 25 of the resistive film 10. Another portion of the input current flows from terminal 20 towards the output terminal 30, which is formed over the entirety of edge 35 of the resistive film 10. Output terminal 30 is coupled to a resistive load 13 having a resistance Rl. Edges 22, 35, and 25, corresponding to the input, output, and common terminal, are all parallel with the vertical axis. Each of the input terminal 20, output terminal 30, and common terminal 40, are formed over the entirety of their corresponding edges 22, 35, and 25. Although not shown in FIG. 2A, due to technological reasons, a terminal may be formed with a small overlap over its corresponding edge.

In order to obtain the desired uniformity of the electric field and of the current density lines (and thus no current crowding), the geometry of the attenuator shown in FIG. 2A and resistances Rs and Rl are related as described in the following paragraphs.

When the current density lines are uniform, the following analysis applies. The aspect ratio formed by the length of edge 50 divided by length of edge 25 of the resistive film determines a resistance between the input and the common terminal 40 (Ric); similarly, the aspect ratio established by edge 11 divided by the length of edge 35 determines a resistance between the input and the output terminal (Rio). When the ratio (Rio+Rl)/Ric equals the ratio of the lengths of edges 25 and 35, current density lines throughout the resistive film 10 are all parallel with one another.

The ratio Rl/(Rio+Rl) will determine the desired attenuation of the attenuator. Taking into account the previously described condition of uniform current density lines, the desired attenuation can be also expressed using geometrical parameters, as the ratio between the length of the edge 55 and the length of the edge 50. In some embodiments, it is desired that the resistance presented by the attenuator to the signal source Ric*(Rio+Rl)/(Rio+Rl+Ric) be equal to Rs, thus power matching the signal source and the loaded attenuator.

Current density lines are shown in FIG. 2B: current density lines 80 from input terminal 20 to output terminal 30 will be parallel with one another, equidistant, and will be further parallel with the current density lines from input terminal 20 to common terminal 40. The electrical field inside the resistive film will be uniform, and the reliability of the device is drastically improved. Thus, for a given set of numerical values of the attenuator shown in FIG. 2A (sheet resistivity and geometrical parameters), it is possible to pre-determine the values of Rl and Rs that result in uniform current density lines.

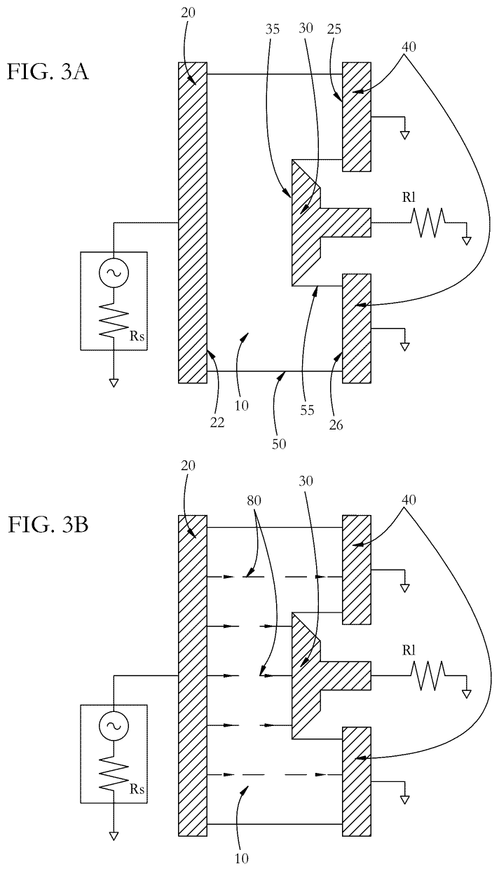

In FIG. 3A a three terminal resistive distributed attenuator with uniform electric field inside a single resistive film 10 is shown, according to the second embodiment of the present invention. The polygonal shaped resistive film 10 has a plurality of edges, each edge being parallel to a vertical axis (e.g., edge 22) or parallel to a horizontal axis (e.g., edge 50). On the largest edge 22 of the polygonal resistive film 10 a conducting input terminal 20 is formed. Input terminal 20 is coupled to an input signal source 12, having a signal source resistance Rs. A portion of the input current flows from terminal 20 towards the common terminal 40, which consists of two sections, one section being formed over the entirety of corresponding edge 25, and another section being formed over the entirety of corresponding edge 26, of the resistive film 10. Another portion of the input current flows from terminal 20 towards the output terminal 30, which is formed over the entirety of edge 35 of the resistive film 10. Output terminal 30 is coupled to a resistive load 13 having a resistance Rl. Edges 22, 35, 25, and 26, corresponding to the input, output, and common terminal, are all parallel with the vertical axis. Each of the input terminal 20, output terminal 30, and common terminal 40, are formed over the entirety of their corresponding edges 22, 35, 25, and 26. Although not shown in FIG. 2A, due to technological reasons, a terminal may be formed with a small overlap over its corresponding edge.

The two sections of the common terminal 40 may be connected together at the level of the system in which the attenuator is used. For example, if the attenuator is used as a surface-mount device (SMD), the two sections will be connected together on the corresponding printed circuit board (PCB).

Although the two edges 25 and 26 corresponding to the two sections of the common terminal 40 are disposed on both sides of the output terminal 30, the edges 25 and 26 do not have necessarily the same length.

In order to obtain the desired uniformity of the electric field and of the current density lines (and thus no current crowding), the geometry of the attenuator shown in FIG. 3A and resistances Rs and Rl are related as described in the following paragraphs.

The analysis for the embodiment shown in FIG. 3A parallels the analysis shown above for FIG. 2A. The only exception is that the single resistance Ric is now composed of two parallel resistances: Ric1 and Ric2. Resistance Ric1 is determined by the aspect ratio formed by the length of edge 50 divided by length of edge 25 of the resistive film. Likewise, resistance Ric2 is determined by the aspect ratio formed by the length of edge 50 divided by length of edge 26 of the resistive film. Thus, the equations shown above for FIG. 2A as a condition for obtaining electric field and current density lines uniformity, to obtain a desired attenuation, and to obtain power match with the signal source continue to apply (after replacing Ric=Ric1*Ric2/(Ric1+Ric2)).

As a calculation example for the embodiment shown in FIG. 3A, when the ratio of the lengths of edges 55 and 50 is 1:4, the desired attenuation of the attenuator is 12 dB. To ensure the uniformity of the density current lines as explained in this invention, the equation: (Rio+Rl)/Ric equals the ratio of the sum of lengths of edges 25 and 26 (on the numerator), and the length of edge 35 (on the denominator). For power matching the signal source, the equation: Ric* (Rio+Rl)/(Rio+Rl+Ric)=Rs must hold. These equations allow to pre-determine Rs and Rl.

Current density lines are shown in FIG. 3B: current density lines 80 from input terminal 20 to output terminal 30 will be parallel with one another, equidistant, and will be further parallel with the current density lines from input terminal 20 to common terminal 40, on both sections of terminal 40. The electrical field inside the resistive film will be uniform, and the reliability of the device is drastically improved. Thus, for a given set of numerical values of the attenuator shown in FIG. 3A (sheet resistivity and geometrical parameters), it is possible to pre-determine the values of Rl and Rs that result in uniform current density lines.

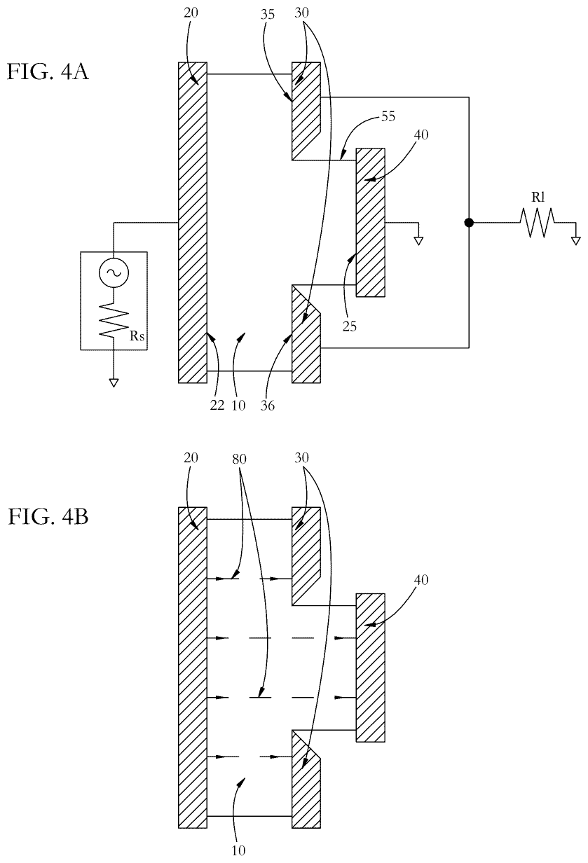

In FIG. 4A a three terminal resistive distributed attenuator with uniform electric field inside a single resistive film 10 is shown, according to the second embodiment of the present invention. While the difference between FIGS. 3A and 2A is that the common terminal 40 consists of two sections instead of one section, in FIG. 4A the output terminal 30 consists of two sections instead of one section. The analysis and the equations shown for FIG. 2A apply for FIG. 4A, and will not be repeated here for brevity. In these equations, resistance Rio will be replaced by: Rio1*Rio2/(Rio1+Rio2). The desired attenuation will be the ratio of the lengths of edges 55 and 50. Similar to the discussion for FIG. 3A, in FIG. 4A the two sections of the output terminal 30 may be connected together at the level of the system in which the attenuator is used.

The attenuators shown in FIGS. 2A, 3A, and 4A, may be built onto an insulating substrate using methods well known in the art. For example, the resistive film and the terminals may be deposited successively. For example, the resistive film may be a sputtered titanium-tungsten film having a thickness of 0.3 microns. The terminals may have a thickness of 3 microns and may be formed by sputtering aluminum.

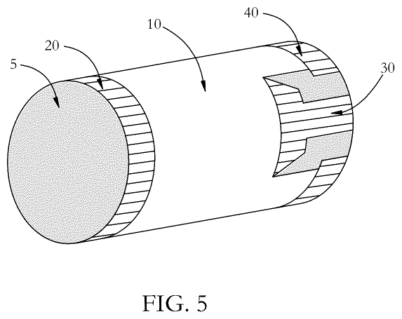

In FIG. 5 a three terminal resistive distributed attenuator with uniform electric field is shown according to the fourth embodiment of the present invention. The structure from FIG. 5 is best understood as the structure shown in FIG. 3A, wrapped around an insulating cylinder or a rod 5. Thus, input terminal 20 is now formed as a cylindrical ring. Terminal 40 is now formed as a slotted cylindrical ring. Terminal 30 has a curved “T” shape.

In some embodiments, the structure is deposited onto the insulating cylinder 5. In other embodiments, the structure from FIG. 3A is first deposited on a flexible, insulating sheet (such as mylar). Subsequently, the processed flexible sheet is wrapped around, and affixed to, cylinder 5. Yet in other embodiments, the flexible sheet processed in accordance with any embodiment from this invention may be delivered by an attenuator manufacturer in order to be installed in a diversity of applications. For example, the processed flexible sheet may be affixed conformally to an object of an arbitrary shape, not just a cylinder. Or, the processed flexible sheet may be mounted in a hybrid electronic system comprising stacked printed circuit boards (PCBs).

In yet some other embodiments, the structures shown in this invention may be built onto a planar dielectric layer, as part of the processing of an integrated circuit. The dielectric layer may be silicon dioxide or silicon nitride. In this case, the resistive film sheet and the terminals will be build using techniques specific to the manufacturing of integrated circuits.

It will be clear to one skilled in the art that the above embodiments may be altered in many ways without departing from the scope of the invention. In particular, the invention may include structures which, although perform an attenuation function as explained above, are primarily used for other purposes. All these devices are “attenuators” for the purpose of this patent. One such example may be an impedance matching device. Accordingly, the scope of the invention should be determined by the following claims and their legal equivalents.

What is claimed is:

1. An attenuator, comprising:
a single resistive film sheet shaped as a polygon, wherein the polygon has a plurality of edges, each edge being parallel with either a horizontal axis or a vertical axis;
an input terminal, the input terminal being formed over the entirety of a corresponding edge of the input terminal;
a common terminal being formed over the entirety of a corresponding edge or edges of the common terminal; and
an output terminal being formed over the entirety of a corresponding edge or edges of the output terminal;
wherein the corresponding edges of the input terminal, of the common terminal, and of the output terminal, are parallel to one another and are further parallel to one of the horizontal axis or the vertical axis; and
wherein, in response:
to coupling a signal source, having a pre-determined source resistance, between the input terminal and the common terminal, and
to coupling a resistive load, having a pre-determined load resistance, between the output terminal and the common terminal;
current density lines throughout the resistive thin film sheet are configured to be substantially parallel to one another.

2. The attenuator of claim 1, wherein the output terminal is formed over a plurality of corresponding edges.

3. The attenuator of claim 1, wherein the common terminal is formed over a plurality of corresponding edges.

4. The attenuator of claim 1, wherein the resistive film is deposited on an insulating cylinder or rod.

5. The attenuator of claim 1, wherein the resistive film is deposited on an insulating flexible sheet, and wherein the attenuator is configured to be installed in a diversity of applications.

6. The attenuator of claim 1, wherein the resistive film is built onto the surface of an integrated circuit, and wherein the attenuator is configured to be coupled to the integrated circuit.

7. The attenuator of claim 1, wherein, in further response to the coupling the signal source and the coupling the resistive load, the signal source and the attenuator are power matched.
